(19) United States
(12) Patent Application Publication
(10) Pub. No.: US 2024/0173855 A1
(43) Pub. Date: May 30, 2024

(54) Method for Generating Training Data for a Machine Learning (ML) Model

(71) Applicant: Siemens Aktiengesellschaft, Muenchen (DE)

(72) Inventors: Ingo THON, Grasbrunn (DE); Ralf GROSS, Nürnberg (DE)

(21) Appl. No.: 18/283,228

(22) PCT Filed: Mar. 4, 2022
(86) PCT No.: PCT/EP2022/055598

§ 371 Date: Sep. 21, 2023

(30) Foreign Application Priority Data
Mar. 22, 2021 (EP) 21163933

(51) Int. Cl. B25J 9/16

(52) U.S. Cl. CPC B25J 9/1612; B25J 9/163

(57) ABSTRACT

The invention relates to a method for generating training data for an ML model. The training data is designed to configure the ML model using a machine learning method. In particular, the ML model is designed to be used as part of a method for ascertaining control data for a gripping device for gripping an object. The invention is characterized by the steps of: —selecting an object, —selecting starting data of the object above a flat surface, —generating a falling movement of the object in the direction of the flat surface beginning with the starting data, —capturing an image of the object after the movement of the object has come to a standstill on the flat surface, —assigning an identifier to the captured image, said identifier comprising ID information for a stable position assumed by the object, wherein the stable position assumed by the object is designed and configured such that all of the object position data that can be converted into one another by means of a movement and/or rotation about a surface normal of the flat surface is assigned to the assumed stable position, and—storing the training data comprising the captured image and the identifier assigned thereto.

### CROSS-REFERENCE TO RELATED APPLICATIONS

This is a U.S. national stage of application No. PCT/EP2022/055598 filed 4 Mar. 2022. Priority is claimed on European Application No. 21163933.1 filed 22 Mar. 2021, the content of which is incorporated herein by reference in its entirety.

### BACKGROUND OF THE INVENTION

### 1. Field of the Invention

The present invention relates to a method for generating training data for a machine learning (ML) model, where the training data are established to configure the ML model by using a machine learning method, and where the ML model is utilized as part of a method for ascertaining control data for a gripping device.

### 2. Description of the Related Art

U.S. Pub. No. 2020/0164531 A1 discloses an exemplary system for gripping items, which comprises a recognition device for recognizing the identity, a location and an alignment of an object and a selection system for selecting a grip point for a particular object. The grip point can be selected by a user, for example. Furthermore, these grip points selected by users allow the system to use a machine learning method to learn the best grip points for an object over time.

A disadvantage of the prior art is that the grip points for gripping an arbitrary object must always ultimately be determined by a user. This firstly takes a large amount of time and secondly it is flawed because the assessment by the user may also be flawed.

### SUMMARY OF THE INVENTION

In view of the foregoing, it is therefore an object of the present invention to provide a method or system that allows an item to be gripped more easily where such a method or system can facilitate safer, more reliable, faster and/or more highly automated gripping, for example, compared with the prior art.

This and other objects and advantages are achieved in accordance with the invention by a method that generates training data for a machine learning (ML) model, where the training data configure the ML model by using a machine learning method, where method comprises selecting an item, selecting starting data relating to the item above a planar surface, producing a falling motion for the item in the direction of the planar surface beginning with the starting data, capturing an image of the item after a motion of the item has stopped on the planar surface, assigning an identifier to the captured image, where the identifier comprises ID information for a stable attitude adopted by the item, and the method includes storing the training data comprising the captured image and the identifier assigned to the image.

In one advantageous embodiment, the ML model is established to be used as part of a method for ascertaining control data for a gripping device for gripping an item.

The use of an ML model trained with these training data allows a method or system to be provided that permits an item to be gripped more easily. As already explained as part of the present disclosure, restricting the possible attitudes considered for an item to stable attitudes according to the present disclosure leads to faster, more reliable and/or more highly automated gripping being facilitated via a system or method of such a configuration.

In one advantageous embodiment, the inventive method is performed repeatedly, —e.g., in each case with different starting data for the item. This allows a greater number of images with an assigned identifier to be produced for training the ML model. The method can be repeated, for example, so often that multiple (advantageously also all) instances of the possible stable attitudes of the item on the planar surface are depicted in at least one of the images. In a further advantageous embodiment, the method can be repeated, for example, so often that as many as possible (advantageously also all) of the possible stable attitudes of the item on the planar surface are depicted in at least two of the images or at least ten of the images.

An item in this case can be any three-dimensional entity having a fixed outer spatial form. Items can be pieces of material, parts, modules, and/or devices, for example.

A gripping device can be configured, for example, as a robot or robot arm having an appropriate gripper for taking hold of or mechanically fixing the item. Such a gripper can be, for example, in a pincer-like form, have one or more suction devices and/or permit or assist in the fixing of an item to be gripped using electromagnetic forces.

A robot or robot arm can be configured, for example, as a 6-axis robot or 6-axis industrial robot or robot arm. Furthermore, such a robot or robot arm can be configured, for example, as a Cartesian robot or can have a corresponding gripper.

Here, the control data for the gripping device for gripping the item at the at least one grip point are data that need to be supplied to a control device of the gripping device or to a control device for the gripping device so that, for example, a gripper of the gripping device mechanically fixes the grasped item at the at least one grip point. Such a control device for the gripping device can be designed and configured, for example, as a robot controller, a programmable logic controller, a computer or a similar control device.

The control data in this case can comprise, for example, the coordinates of a point in space for the gripper and an alignment of the gripper that the gripper must adopt in order to be able to grip the item. Furthermore, the control data can also be the coordinates of the at least one grip point on the item in space, or can comprise these coordinates.

The control device for the gripping device can then use this information to calculate the required movement of the gripping device and of the gripper in a known manner.

Here, coordinates in space are understood to mean, for example, a coordinate system that contains both the item to be gripped and the gripping device.

Control data can then be, for example, coordinates of the at least one grip point and/or of the at least one model grip point that have been transformed into this real space. Furthermore, when calculating the control data, it is possible to take account of not only the coordinates of the at least one grip point but also a position of the item in space in order, for example, to allow a gripper of the gripping device unimpeded access to the at least one grip point.

The image of the item can be captured, for example, via a camera, a scanner (for example, a laser scanner), a distance radar or a similar device for capturing three-dimensional items. The captured image may advantageously be a two-dimensional image of the item, or be a two-dimensional image that comprises a representation of the item. Furthermore, the captured image may also be a three-dimensional depiction of the item, or may comprise such a depiction. ID information may be a unique descriptor, identifier or the like for a stable attitude adopted by an item or may comprise such information.

Stable attitudes of an item, for example, on a surface (e.g., a substantially horizontal plane or surface), refer to those one or more attitudes of the item that the item can be in without moving (e.g., tilting or rolling) from rest of its own accord.

A stable attitude such as this for the item can be ascertained, for example, by bringing the item, e.g., to the surface (e.g., dropping it onto this surface) with an initial motion and then waiting until the item is no longer moving. By repeatedly performing this process under different initial conditions, it is possible to determine the stable attitudes of an item in this way. Here, it is possible for, e.g., the item to be moved onto a corresponding surface (e.g., thrown onto it or dropped onto it) under a wide variety of initial conditions. A period of time is then waited until the item is no longer moving. The adopted stable attitude is then subsequently captured as appropriate.

A stable attitude can be captured, defined and/or stored, for example, by logging the adopted attitude. This logging can be performed, e.g., via image recording, 3D recording and/or capture of one or more coordinates of the item in the stable attitude. Furthermore, the capture of the stable attitude can also comprise assigning an identifier unique to the stable attitude of the item.

All of those captured attitude data for a specific item that can be translated into one another via a shift and/or a rotation about a surface normal of the planar surface that the item is on can be assigned to a specific stable attitude. All of these attitudes can then be assigned, e.g., a specific identifier or specific ID information for the associated stable attitude.

In particular, specific ID information or a specific identifier for a stable attitude of an item is assigned to all of those attitudes of this item, or to the corresponding images, that can be translated into one another via a shift and/or a rotation about a surface normal of a bearing surface that the item is located on.

By way of example, the assignment of the ID information to the stable attitude adopted by the item is established such that this ID information is assigned to all of those attitude data, or corresponding images, relating to the item that can be translated into the stable attitude adopted by the item by way of a shift and/or a rotation about a surface normal of the planar surface.

By way of example, stable attitudes of an item can be ascertained in a semiautomated manner by virtue of a user selecting a specific item and then dropping it onto a surface or throwing it onto the surface under a wide variety of initial conditions, for example. A period of time is subsequently waited until the item has come to rest. An image of the item is then captured and an automatic image analysis method is used to check whether the attitude of the captured item can be transformed into an already captured attitude of the item via a shift and/or rotation about a surface normal of the surface. If this is the case, then the identifiers for this stable attitude are then automatically also assigned to the image that has now been recorded.

If the attitude now captured for the item cannot be transformed into the attitude of an already captured item or item image as appropriate, then the image that has now been recorded is assigned a new identifier for the stable attitude of the item that is adopted in the image. These last steps can then occur in an automated manner.

In another embodiment, the ascertainment can also occur in an automated manner, for example. This can be achieved by using, for example, a physical simulation of a falling motion of a 3D model of an item onto a surface. As part of this simulation, a period of time is then waited until the motion of the 3D model of the item has come to rest. An appropriate image of the now resting 3D model of the item is then recorded and the image is assigned an identifier for a stable attitude using the method already explained above. This process can then be repeated automatically under randomly selected initial conditions until no further new stable attitudes have been found, or a sufficient quantity of images is available for each of the stable attitudes found.

A sufficient quantity of images may exist, for example, if 2, 10 or even 50 images are available for each stable attitude. Furthermore, it is possible to stipulate that no further new stable attitude is found if a further new stable attitude is not found after 10, 50 or even 100 attempts.

By way of example, the images assigned to a specific stable attitude can furthermore be stored as appropriate in a database. This database can then be used, for example, to assign a specific stable attitude to a newly captured item via comparison with these images.

Furthermore, the images can be used to train an appropriate neural network or another ML model, which can then be used as part of the image evaluation for newly recorded images of items. By way of example, a neural network or ML model such as this can then be used to supply a recorded image of an item at rest on a surface to the neural network. The result of the evaluation by the neural network or ML model can then be, at least among other things, an identifier for the stable attitude adopted by this item.

An advantage of using the stable attitudes as part of a method in accordance with the disclosed embodiments is, e.g., that only the relatively few stable attitudes, compared with all possible attitudes, need to be taken into account for identification, position determination and/or determination of the grip point. This can reduce, and often even significantly reduce, the computational complexity for position determination, identification and/or determination of the grip point.

A machine learning method is understood to mean, for example, an automated (“machine”) method that does not generate results via rules defined in advance but, rather, that uses a machine learning algorithm or learning method to (automatically) identify regularities from many examples, on the basis of which regularities it is then possible to produce statements about data to be analyzed.

Such machine learning methods can be configured, for example, as a supervised learning method, a partly supervised learning method, an unsupervised learning method or a reinforcement learning method.

Examples of machine learning methods are, e.g., regression algorithms (e.g., linear regression algorithms), production or optimization of decision trees, learning methods or training methods for neural networks, clustering methods (e.g., k-means clustering), learning methods for producing or for support vector machines (SVM), learning methods for producing or for sequential decision models or learning methods for producing or for Bayesian models or networks.

The result of such application of such a machine learning algorithm or learning method to specific data is referred to, in particular in the present disclosure, as a machine learning model or ML model. Such an ML model provides the digitally stored or storable result of application of the machine learning algorithm or learning method to the analyzed data.

The production of the ML model can be established such that the ML model is newly formed by applying the machine learning method, or an already existing ML model is altered or adapted by applying the machine learning method.

Examples of such ML models are results from regression algorithms (e.g., a linear regression algorithm), neural networks, decision trees, the results from clustering methods (including e.g. the clusters or cluster categories, cluster definitions and/or cluster parameters obtained), support vector machines (SVM), sequential decision models or Bayesian models or networks.

Neural networks can be, e.g., deep neural networks, feedforward neural networks, recurrent neural networks, convolutional neural networks or autoencoder neural networks. The application of appropriate machine learning methods to neural networks is frequently also referred to as training the applicable neural network.

Decision trees can be configured, for example, as an iterative dichotomizer 3 (ID3), classification and regression trees (CART) or random forests.

A neural network is understood, at least in the context of the present disclosure, to mean an electronic device that comprises a network of nodes, where each node is generally connected to multiple other nodes. The nodes are also referred to as neurons or units, for example. Each node has at least one input connection and one output connection. Input nodes for a neural network are understood to mean nodes that can receive signals (data, stimuli, and/or patterns) from the outside world. Output nodes of a neural network are understood to mean nodes that can forward signals, data or the like to the outside world. So-called “hidden nodes” are understood to mean nodes of a neural network that are formed as neither an input node nor an output node.

Neural networks and also other ML models in accordance with the present disclosure can be realized, e.g., as computer software and/or a data collection that are storable or stored on a computer, a computer network or a cloud.

The neural network can be formed as a deep neural network (DNN), for example. A deep neural network such as this is a neural network in which the network nodes are arranged in layers (the layers themselves being able to be one-dimensional, two-dimensional or higher-dimensional). A deep neural network comprises at least one or two hidden layers that comprise only nodes that are not input nodes or output nodes. That is, the hidden layers have no connections for input signals or output signals.

Deep learning is understood to mean, for example, a class of machine learning techniques that makes use of many layers of nonlinear information processing for supervised or unsupervised feature extraction and transformation and for pattern analysis and classification.

The neural network can also comprise an autoencoder structure, for example. Such an autoencoder structure can be suitable, for example, for reducing a dimensionality of the data and, for example, thus recognizing similarities and commonalities.

A neural network can also be formed as a classification network, for example, which is particularly suitable for putting data into categories. Such classification networks are used in connection with handwriting recognition, for example.

Another possible structure of a neural network can be a deep believe network, for example.

By way of example, a neural network can also have a combination of several of the aforementioned structures. As such, for example, the architecture of the neural network can comprise an autoencoder structure in order to reduce the dimensionality of the input data, which structure can then furthermore be combined with another network structure, for example, in order to detect special features and/or anomalies within the reduced-data dimensionality, or to classify the reduced-data dimensionality.

The values describing the individual nodes and the connections thereof, including further values describing a specific neural network, can be stored, for example, in a set of values that describes the neural network. Such a set of values is then a configuration of the neural network, for example. If such a set of values is stored after the neural network has been trained, then this means that a configuration of a trained neural network is stored, for example. As such, by way of example, it is possible to train the neural network in a first computer system using appropriate training data, the applicable set of values assigned to this neural network, and then to store and transfer it as a configuration of the trained neural network to a second system.

A neural network can generally be trained by using a wide variety of known learning methods to ascertain parameter values for the individual nodes or for the connections thereof by inputting input data into the neural network and analyzing the then corresponding output data from the neural network. In this way, it is possible to train a neural network with known data, patterns, stimuli or signals in a manner that is known per se today to then subsequently be able to use the thus trained network to analyze further data, for example.

In general, training the neural network is understood to mean that the data used to train the neural network are processed in the neural network using one or more training algorithms in order to calculate or alter bias values (biases), weighting values (weights) and/or transfer functions of the individual nodes of the neural network, or of the connections between two respective nodes within the neural network.

To train a neural network, e.g., in accordance with the present disclosure, it is possible to use one of the “supervised learning” methods, for example. This involves training a network, by training using appropriate training data, in respective results or capabilities associated with these data. A supervised learning method such as this can be used, for example, to train a neural network in the stable attitudes of one or more objects, for example. This can be achieved, for example, by “training” an image of an object that contains the object in a stable attitude in an identifier for the adopted stable attitude (the aforementioned “result”).

Furthermore, an unsupervised training (unsupervised learning) method can also be used to train the neural network. For a given set of inputs, such an algorithm produces a model, for example, that describes the inputs and allows predictions therefrom. By way of example, there are clustering methods that can be used to put the data into different categories if they differ from one another by way of characteristic patterns, for example.

Supervised and unsupervised learning methods can also be combined for training a neural network, for example, if portions of the data have associated trainable properties or capabilities, whereas this is not the case for another portion of the data.

Furthermore, so-called reinforcement learning methods can also be used for training the neural network, at least among other things.

By way of example, a training that requires a relatively high level of computation power from an applicable computer can be carried out on a high-performance system, while other work or data analyses using the trained neural network can then certainly be performed on a lower-performance system. Such other work and/or data analyses using the trained neural network can occur, for example, on an edge device and/or on a control device, a programmable logic controller or a modular programmable logic controller or other appropriate devices in accordance with the present disclosure.

The ML model can be trained via the machine learning method, for example, using a collection of images that shows a specific item in a particular stable attitude on a planar surface, where each of the images have an assigned identifier for the stable attitude adopted in them. The ML model is then trained using this collection of images. A stable attitude for this item can then subsequently be determined by applying the trained ML model to a captured image of the item.

Each of the images in the collection of images can show, for example, a depiction of the item in one of its stable attitudes on a given or predefinable surface, in particular on a planar surface or on a substantially horizontal, planar surface. The collection of images then contains, e.g., a plurality of representations of the item in a particular one of its stable attitudes and furthermore at particular different angles of rotation relative to a defined or definable initial attitude on a surface. The rotation may be defined, e.g., for a surface normal of a surface that the item is on in one of its stable attitudes.

The ML model may be formed as a neural network, for example, in which case the machine learning method may be a supervised learning method for neural networks, for example.

In a further advantageous embodiment, the collection of images used for training the ML model can show different items in particular different stable attitudes, where each of the images can be assigned both ID information for the represented item and an identifier for the stable attitude adopted in said image. By applying an ML model trained with such a collection of images to a specific captured item, it is then possible to ascertain both ID information for the item and an identifier for the stable attitude adopted by this item.

For this, the collection of images may be configured, for example, such that each of the images shows a depiction of one of the items in one of its stable attitudes on a given or predefinable surface, in particular on a planar surface or on a substantially horizontal, planar surface. The collection of images can then contain, e.g., a plurality of representations of the various items in a particular one of their stable attitudes and at particular different angles s of rotation relative to a defined or definable initial attitude. The rotation may be defined, e.g., with respect to a surface normal of a surface that the item is on in one of its stable attitudes.

Here, the ML model may also be formed as a neural network, for example, the associated machine learning method can be a supervised learning method for neural networks, for example, here too.

The ML model may be formed and configured as a “detection ML model”, for example. Such a detection ML model may be configured, for example, to detect a location of the item and/or of a virtual frame around the item, a type or ID information for the item and/or a stable attitude of the item. Furthermore, an ML model in accordance with the present disclosure can comprise such a detection ML model. Such a detection ML model may formed and configured as a deep neural network, for example. The input data provided or used for such a detection ML model can be the captured image of the item, for example. Output data from such a detection ML model may then be for example one, several or all of the aforementioned parameters, for example.

In another embodiment, the detection ML model may furthermore be configured to detect a location, a virtual frame, a type and/or ID information for each of multiple or all items represented in a captured image. A detection ML model in such a form can advantageously then be used, for example, if there are further items in the captured image of the item.

Output data from a detection ML model established in such a way may then be, for example, the aforementioned information regarding the item for each of the captured items: data relating to a location and/or virtual frame and/or ID information. This information can then be used, for example, in a further method step to select the item to be grasped from all of the captured items, for example, based on the ascertained ID information. The item parameters then already ascertained by this detection ML model can be used as part of a method in accordance with the disclosed embodiments to ascertain the control data for the gripping device for gripping the item.

Furthermore, the ML model may be configured, for example, as an “angle detection ML model”, which is configured at least among other things to detect an angle of rotation of the item on a surface with reference to a stipulated or stipulable initial position. An ML model in accordance with the present disclosure can also comprise such an angle detection ML model. Such an angle detection ML model may be designed and configured, for example, as a regression AI model or a classification AI model.

The input data used for such an angle detection ML model can again be the captured image of the item. Output data in this case may again be, for example, an applicable angle of rotation of the item on the setdown surface with reference to a stipulated or stipulable initial position, or can comprise such an angle of rotation. Furthermore, output data from an angle detection ML model can also comprise the aforementioned angle of rotation, plus the data that were indicated above by way of illustration from output data from a detection ML model.

In another embodiment, the ML model may be configured, for example, as a “transformation ML model” that is configured to ascertain transformation data for transforming from a stipulated or stipulable initial position of the item into the position of the captured item on the setdown surface in the real world. Input data for such a transformation ML model may be, for example, identifier data for the item, a stable attitude of the item and/or an angle of rotation of the item on the setdown surface with reference to a stipulated or stipulable initial position. Identifier data for the item may be, e.g., ID information, description data for a virtual frame around the item, information regarding a stable attitude and/or scaling data.

Furthermore, input data for such a transformation ML model may also be captured image data relating to an item on a planar surface. The aforementioned input data, such as the identifier data for the item, a stable attitude of the item and/or an angle of rotation of the item, can then be obtained, for example, from these image data in a first step, where the process is then continued in accordance with the explanation provided above. Furthermore, the captured image data relating to the item on the planar surface can also be used directly as input data for an applicable transformation ML model.

Output data from such a transformation ML model may then be, for example, transformation data for the aforementioned transformation of the item from the stipulated or stipulable initial position into the real position of the item on the setdown surface. Such a stipulated or stipulable initial position of the item may be, for example, the position of a 3D model of the item in an applicable 3D modeling program (e.g. 3D CAD software). This also applies to the initial position used for the angle of rotation, for example.

Such a transformation ML model may be configured, for example, as a deep neural network or a random forest model.

An ML model in accordance with the present disclosure can comprise, for example, a detection ML model and/or an angle detection ML model and/or a transformation ML model. Moreover, a further ML model in accordance with the present disclosure can comprise, for example, a detection ML model and/or an angle detection ML model and/or a transformation ML model.

In one advantageous embodiment, an ML model in accordance with the present disclosure can furthermore comprise, for example, a detection ML model and/or an angle detection ML model, or may be formed and configured as such an ML model. In this embodiment, a further ML model in accordance with the present disclosure can comprise, for example, a transformation ML model, or may be formed and configured as such a transformation ML model.

Furthermore, the starting data may be provided, for example, by a height of the item, such as a center of gravity of the item, above the planar surface, an alignment of the item in space and a vector for an initial velocity of the item.

The falling motion may be, for example, a motion under the influence of the force of gravity. Furthermore, additional forces, such as frictional forces (e.g., in air or in a liquid) and electromagnetic forces can furthermore influence the motion. In one advantageous embodiment, the motion is dominated by the force of gravity, for example. Here, the falling motion begins in accordance with the starting data.

By way of example, the ML model may be formed and configured as a detection ML model in accordance with the present disclosure or can comprise such a model. Here, the identifier assigned to the captured image can comprise not only the ID information for the stable attitude adopted by the item but also, for example, further item parameters in accordance with the present disclosure. Such further item parameters can comprise, e.g., information regarding an attitude and/or position of the item, information regarding an attitude and/or shape of a virtual frame around the item, a type of the item and/or ID information regarding the item.

By way of example, the ML model may also be formed and configured as an angle detection ML model in accordance with the present disclosure or can comprise such a model. Here, the identifier assigned to the captured image can comprise not only the ID information for the stable attitude adopted by the item but also, for example, further item parameters in accordance with the present disclosure. Such further item parameters can comprise, e.g., an angle of rotation of the item on the planar surface with reference to a stipulated or stipulable initial position.

The ML model may furthermore also be formed and configured as a transformation ML model in accordance with the present disclosure or can comprise such a model. Here, the identifier assigned to the captured image can comprise not only the ID information for the stable attitude adopted by the item but also, for example, further item parameters in accordance with the present disclosure. Such further item parameters can comprise, e.g., data for the aforementioned transformation of the item from the stipulated or stipulable initial position into the real position of the item on the planar surface. Here, such a stipulated or stipulable initial position of the item may also be, for example, the position of a 3D model of the item in an applicable 3D modeling program (e.g., 3D CAD software).

At least some of the identifier parameters and/or item parameters that are both mentioned above can be ascertained manually, for example, by a user, such as manually via a measurement or using an at least semiautomated measurement system. Furthermore, at least some of such identifier parameters can be ascertained automatically, for example, via image evaluation methods or additional automatic measurement systems, such as an optical measurement system, a laser measurement system and/or an acoustic measurement system.

In a further advantageous embodiment, a method for generating training data for a transformation ML model may be configured via a method comprising selecting an item, selecting starting data relating to the item above a planar surface producing a falling motion for the item in the direction of the planar surface capturing an image of the item after the motion of the item has stopped on the planar surface ascertaining at least one item parameter of the item by using the captured image, the at least one item parameter comprising identifier data for the item, an attitude or position of the item, information regarding a virtual frame around the item, an identifier for a stable attitude of the item and/or an angle of rotation of the item on the planar surface, and comprising assigning an identifier to the ascertained at least one item parameter, where the identifier comprises transformation data for transforming the item from a stipulated or stipulable initial position into a real position of the item on the planar surface.

The real position of the item in this instance is described, for example, by the identifier data for the item, the attitude or position of the item, the information regarding a virtual frame around the item, the identifier for a stable attitude of the item and/or an angle of rotation of the item.

Identifier data for the item may be or may comprise, for example, ID information, description data for a virtual frame around the item, ID information regarding a stable attitude and/or scaling data.

The transformation data, the stipulated or stipulable initial position, the angle of rotation of the item, the identifier for a stable attitude of the item and the at least one item parameter may be configured in accordance with the present disclosure. Furthermore, the attitude or position of the item and/or the information regarding a virtual frame around the item may also be configured in accordance with the present disclosure.

The object and advantages are also achieved in accordance with the invention by a method for generating training data for an ML model, where the training data configure the ML model by using a machine learning method, where the method comprises electing a 3D model of an item, selecting starting data relating to the 3D model of the item above a virtual planar surface, simulating a falling motion for the 3D model of the item in the direction of the virtual planar surface, creating an image of the 3D model of the item after the simulated motion of the 3D model of the item has stopped on the virtual planar surface, assigning an identifier to the created image, where the identifier comprises ID information for the stable attitude adopted by the 3D model of the item, and storing the training data comprising the captured image and the identifier assigned to said image.

Such a method may be configured in accordance with the disclosed embodiments.

Furthermore, the method may be established such that the ML model is configured to be used as part of a method for ascertaining control data for a gripping device for gripping an item. The training data can be stored in a storage device and/or, for example, in a database or data collection for applicable training data.

The ML model may be configured in accordance with the disclosed embodiments, for example. Furthermore, the machine learning method, the control data, the gripping device, the item, the starting data, the identifier and the stable attitude may be configured in accordance with the disclosed embodiments.

As already explained in connection with the disclosed embodiments of the inventive method, the use of an ML model trained with these training data facilitates a method or system that permits an item to be gripped more easily.

A 3D model may be any digital depiction or representation of the item that substantially represents at least the outer shape. The 3D model advantageously represents the outer shape of the item. Furthermore, the 3D model can also contain information about the internal structure of the item, mobilities of components of the item or information about functionalities of the item.

The 3D model may be stored, e.g., in a 3D file format, for example, may have been created using a 3D CAD software tool. Examples of such software tools are for example SolidWorks (file format: .sldprt), Autodesk Inventor (file format: .ipt), AutoCAD (file format: .dwg), PTC ProE/Creo (file format: .prt), CATIA (file format: .catpart), SpaceClaim (file format: scdoc) or SketchUp (file format: skp). Other file formats may be, for example, .blend (Blender file), . dxf (Drawing Interchange Format), .igs (Initial Graphics Exchange Specification), .stl (stereolithography format), .stp (Standard for the Exchange of Product Model Data), .sat (ACIS text file) or .wrl, .wrz (Virtual Reality Modeling Language). File formats in which material properties of the item, such as specific weight, color, and/or material of the item, or its components are also stored can advantageously be used. The use of such 3D models allows, e.g., physically correct simulations to be performed for the item, e.g., in order to determine one or more stable attitudes of the item on a surface.

The 3D model for the item can be selected, for example, using ID information for the item, the at least one item parameter comprising this ID information.

The 3D model can be taken, for example, from a database for 3D models of different items, where the selection from this database can be made, for example, using the aforementioned ascertained ID information. Furthermore, the 3D model can alternatively also be selected by a user. By way of example, the user can select the 3D model from among multiple available 3D models.

In one advantageous embodiment, the inventive method can be performed repeatedly, e.g., in each case with different starting data for the item, for example, in order to produce a plurality of images with an assigned identifier for training the ML model.

The method can be repeated, for example, so often that multiple (advantageously also all) instances of the possible stable attitudes of the digital model of the item on the virtual planar surface are depicted in at least one of the images. In a further advantageous embodiment, the method can be repeated, for example, so often that as many as possible (advantageously also all) of the possible stable attitudes of the digital model of the item on the virtual planar surface are depicted in at least two of the images or at least ten of the images.

Here, the ML model, the item, the capture of the image and the ID information for the stable attitude adopted by the item may also be configured in accordance with the present disclosure.

The starting data may be provided, for example, by a height of the item (e.g., a height of a center of gravity of the item) above the planar surface, an alignment of the item in space and a vector for an initial velocity of the item.

The falling motion can be simulated, for example, as a motion under the influence of the force of gravity. Furthermore, additional forces, such as frictional forces (e.g., in air or in a liquid) and electromagnetic forces can furthermore be taken into account in the simulation. In one advantageous embodiment, the motion is simulated only by taking into account the force of gravity, for example. Here, the simulation of the falling motion then begins in accordance with the starting data.

The ML model may be configured, for example, as a detection ML model in accordance with the present disclosure or can comprise such a model. Here, the identifier for the created image can comprise not only the ID information for the stable attitude adopted by the 3D model of the item but, may also comprise, for example, further item parameters according to the present description. Such further item parameters can comprise, e.g., information regarding an attitude and/or position of the 3D model of the item, information regarding an attitude and/or shape of a virtual frame around the 3D model of the item, a type of the item and/or ID information regarding the item.

By way of example, the ML model may also be formed and configured as an angle detection ML model in accordance with the present disclosure or can comprise such a model. Here, the identifier assigned to the captured image can comprise not only the ID information for the stable attitude adopted by the 3D model of the item but can also comprise, for example, further item parameters in accordance with the present disclosure. Such further item parameters can comprise, e.g., an angle of rotation of the 3D model of the item on the virtual planar surface with reference to a stipulated or stipulable initial position.

The ML model may also be configured, for example, as a transformation ML model in accordance with the present disclosure or can comprise such a model. Here, the identifier assigned to the captured image can comprise not only the ID information for the stable attitude adopted by the 3D model of the item but may also comprise, for example, further item parameters in accordance with the present disclosure. Such further item parameters can comprise, e.g., transformation data for the aforementioned transformation of the 3D model of the item from a stipulated or stipulable initial position into the real position of the item on the setdown surface. Here, such a stipulated or stipulable initial position of the 3D model of the item may also be, for example, the position of the 3D model of the item in an applicable 3D modeling program (e.g., 3D CAD software).

In one advantageous embodiment, the identifier parameters and/or item parameters that are both mentioned above can be ascertained automatically, for example. All size data, attitude data and other data relating to the item that describe an attitude and/or position are known in the digital simulation environment (otherwise a simulation of the item, in particular a physical simulation, would not be possible). Consequently, a position of the item, an attitude of the item, an angle of rotation of the item with reference to the virtual planar surface, transformation data in accordance the present disclosure and further comparable item parameters relating to the 3D model of the item can be taken directly from the simulation system. It is thus possible for a method for generating training data as described above to occur automatically using a 3D model of the item and as such for training data for an ML model to be generable or generated automatically in accordance with the present disclosure.

However, at least some of the identifier parameters mentioned above can also be ascertained manually by a user, for example, manually via a measurement or using an at least semiautomated measurement system. Furthermore, at least some of such identifier parameters can be ascertained automatically for example by way of image evaluation methods or additional automatic digital measurement in systems a simulation environment for performing the method in accordance with disclosed embodiments, here.

In a further advantageous embodiment, a method for generating training data for a transformation ML model may be established by selecting a 3D model of an item selecting starting data relating to the 3D model of the item above a virtual planar surface simulating a falling motion for the 3D model of the item in the direction of the virtual planar surface, creating an image of the 3D model of the item after the simulated motion of the 3D model of the item has stopped on the virtual planar surface, ascertaining at least one item parameter relating to the 3D model of the item by using the created image, where the at least one item parameter comprises identifier data for the item, an attitude or position of the 3D model of the item, information regarding a virtual frame around the 3D model of the item, an identifier for a stable attitude of the 3D model of the item and/or an angle of rotation of the 3D model of the item on the planar surface, by assigning an identifier to the ascertained at least one item parameter, where the identifier comprises transformation data for transforming the 3D model of the item from a stipulated or stipulable initial position into an ascertained position of the 3D model of the item on the virtual planar surface, and by storing the training data comprising the at least one item parameter and the identifier assigned to the item parameter.

The training data can be stored in a storage device and/or, for example, in a database or data collection for applicable training data.

The ascertained position of the item is described, for example, by the identifier data for the 3D model of the item, an attitude or position of the 3D model of the item, information regarding a virtual frame around the 3D model of the item, the identifier for a stable attitude of the 3D model of the item and/or an angle of rotation of the 3D model of the item.

Identifier data for the 3D model of the item may be or nay comprise, for example, ID information, description data for a virtual frame around the 3D model of the item, ID information for a stable attitude and/or scaling data.

The transformation data, the stipulated or stipulable initial position, the angle of rotation of the 3D model of the item, the ID information or identifier for a stable attitude of the 3D model of the item and the at least one item parameter may be configured in accordance with the present disclosure. Furthermore, the attitude or position of the 3D model of the item and/or the information regarding a virtual frame around the 3D model of the item may also be designed and configured in accordance with the present disclosure.

The at least one item parameter may be or may comprise, for example, an identifier relating to the item, ID information regarding the item and/or a name or a short description or description of the item. The identifier may be configured, for example, such that it permits the item to be identified. ID information in this instance may be a unique descriptor, and/or identifier for the respective item or can comprise such information.

Furthermore, the at least one item parameter can comprise, for example, an attitude, position or the like relating to the captured item. Such an attitude may be provided, for example, by characteristic points and the attitude of the characteristic points and/or may, for example, also be defined by an attitude or position of a virtual bounding frame in the captured image, a bounding box. Furthermore or additionally, such an attitude or position may, for example, also be provided by the attitude of a central point on the item (e.g., a center of gravity) and an angle of rotation relative to a defined or definable standard attitude.

Furthermore, the at least one item parameter can also comprise a property of the item, such as a color, a material or a material combination or comparable properties.

The determination of the at least one item parameter for the captured item relates to the item depicted in the captured image. The at least one item parameter is thus assigned to the item depicted in the captured image, as depicted in the captured image.

The objects and advantages are furthermore achieved in accordance with the invention by a method for generating training data for an ML model, where the method comprises selecting a 3D model of an item, selecting a virtual planar surface, determining an attitude of the 3D model of the item in such a way that the 3D model of the item touches the virtual planar surface at three or more points, creating an image of the digital model of the item, assigning an identifier to the image, where the identifier comprises ID information for the stable attitude adopted by the 3D model of the item, and storing the training data comprising the created image and the identifier assigned to said image.

The training data can be stored in a storage device and/or, for example, in a database or data collection for applicable training data.

The ML model may be configured in accordance with the present disclosure, for example. Furthermore, the described method for generating training data for an ML model may be configured in accordance with the present disclosure.

In one advantageous embodiment, the method can also be performed repeatedly here, for example, in order to generate as great as possible a number of images with an assigned identifier for training the ML model. The method can be repeated for example so often that multiple (advantageously also all) instances of the possible stable attitudes of the digital model of the item on the virtual planar surface are depicted in at least one of the images. In a further advantageous embodiment, the method can be repeated, for example, so often that as many as possible (advantageously also all) of the possible stable attitudes of the digital model of the item on the virtual planar surface are depicted in at least two of the images or at least ten of the images.

The disclosed embodiments of the method for generating training data can furthermore be established such that the respective methods are furthermore configured to train an ML model in accordance with the present disclosure, or to train a further ML model in accordance with the present disclosure, such that the ML model or the further ML model is trained using the captured or ascertained image and at least the ID information assigned to said image for the stable attitude adopted by the item or the stable attitude adopted by the 3D model of the item.

By way of example, the ML model and/or the further ML model may be formed and configured as a detection ML model and/or an angle detection ML model and/or a transformation ML model, or can comprise such ML models. The ML model and/or the further ML model can thus comprise the function of one, two or all three of said ML models.

In another embodiment, the ML model may be configured, for example, as a detection ML model and/or an angle detection ML model, while the further ML model may be configured, for example, as a transformation ML model.

In one advantageous embodiment, the method can be used, for example, to train a detection ML model in accordance with the present disclosure, an angle detection ML model according to the present description and/or a transformation ML model in accordance with the present disclosure.

The ML model and/or the further ML model can furthermore be trained, for example, using the captured image of the item, a position of the item, ID information regarding the item, an angle of rotation of the item and/or an identifier relating to a stable attitude adopted by the item. The ML model and/or the further ML model are trained, for example, by assigning the position of the item, the ID information regarding the item, the angle of rotation of the item and/or the identifier relating to the stable attitude adopted by the item to the captured image of the item. Such assignment of parameters (to the captured image here) is also referred to quite generally as “labelling”.

An ML model formed as a detection ML model can be trained by labelling the captured image, for example, with a position of the item, ID information regarding the item and/or an identifier relating to a stable attitude adopted by the item.

Furthermore, an ML model formed as a rotation detection ML model can be trained, for example, by labelling the captured image of the item with a position of the item, ID information regarding the item, an angle of rotation of the item and/or an identifier relating to a stable attitude adopted by the item.

An ML model formed as a transformation ML model can be trained by labelling the captured image, for example, with appropriate transformation data for transforming an initial attitude of the item into the attitude adopted in the captured image.

Furthermore, an ML model formed as a transformation ML model can be trained by labelling at least one item parameter according to the present description ascertained using the captured or created image, for example, with appropriate transformation data for transforming an initial attitude of the item into the attitude adopted in the captured or created image.

The objects and advantages are furthermore achieved in accordance with the invention by the use of training data generated using a method for generating training data in accordance the present disclosure for configuring an ML model, in particular an ML model in accordance with the present disclosure.

Furthermore, the objects and advantages are achieved in accordance with the invention by an ML model in accordance with the present disclosure, the ML model having been configured using training data generated in accordance with the present disclosure.

The objects and advantages are furthermore achieved in accordance with the invention by a method for ascertaining control data for a gripping device by using an ML model that has been configured using training data generated in accordance with the present disclosure, where the method comprises capturing an image of the item, determining at least one item parameter for the captured item, ascertaining control data for a gripping device for gripping the item at least one grip point, where the at least one grip point on the item is furthermore ascertained using the ML model, and the at least one item parameter is particularly determined and/or the control data for the gripping device is ascertained using the ML model.

The ML model, in this instance, may be configured in accordance with the present disclosure, for example.

By way of example, the item, the capture of an image of the item and the at least one item parameter may be configured in accordance with the present disclosure.

In one advantageous embodiment of the method, ascertaining the at least one grip point on the item involves the captured image of the item being analyzed using the ML model. In particular, determination of the at least one item parameter and/or ascertainment of the control data for the gripping device involves the captured image of the item being analyzed using the ML model.

The configuration of the ML model involved using training data in accordance with the present disclosure. As a result, the analysis occurs using information about at least one stable attitude of the items under consideration.

The aforementioned embodiment is based on the insight that when analyzing the image of the item, for example, in order to identify the item or determine further item parameters, it is not necessary to take account of all possible alignments of the item, but rather it can be assumed that the item is in one possible stable attitude. This considerably restricts the number of possibilities for the possible attitudes of the item during the applicable image analysis. This allows corresponding analysis methods for identifying the item and/or determining its attitude to proceed more simply and/or more quickly. The resultant ascertainment of an appropriate grip point for this item is thus also simplified further compared with the prior art.

Furthermore, the at least one grip point on the item can also be ascertained more easily, more quickly and/or more efficiently if ascertaining the at least one grip point involves using information regarding at least one possible stable attitude of the item. This can be accomplished, e.g., by analyzing the captured image of an item using an ML model in accordance with the present disclosure. Limiting the algorithms used for the image analysis to possible stable attitudes of the item permits a clear reduction in analysis effort, because a large proportion of possible attitudes of the item can be ignored.

Information regarding at least one possible stable attitude of an item may be configured, e.g., as an ML model (machine learning model) in accordance with the present disclosure. Here, the ML model was trained and/or configured, e.g., by applying a machine learning method to ascertained information regarding the at least one possible stable attitude. By way of example, such an ML model may be formed and configured as a neural network.

A use of information regarding the at least one possible stable attitude of the item is understood to mean any use of such information when calculating or ascertaining data or information. As such, for example, the use of an ML model in accordance with the present disclosure that has been trained or configured using training data in accordance with the present disclosure constitutes a use of information according to a possible stable attitude of an item.

As such, for example, identifying an item, or determining an attitude of the item, can involve using an applicable ML model. A 3D model of the item can also be selected in a comparable manner by using an ML model according to the present description. By way of example, one of the method sequences explained above can be used to ascertain ID information regarding the item by using the ML model, and this ID information can then be taken as a basis for selecting an applicable 3D model, for example, from an applicable database.

Furthermore, it is also possible both to determine the at least one grip point on the item and to ascertain control data for the gripping devices in accordance with the present disclosure in a comparable manner by using the ML model.

As such, the ML model can again be used, by way of example, to determine the at least one item parameter for the captured item such that an identifier for the stable attitude of the item, an angle of separation from a stipulated zero point and/or an angle of rotation with reference to a surface normal to the setdown surface for the item is ascertained for the item. This information can then be taken as a basis, for example, for stipulating transformation data for transforming a 3D model of the item, including a model grip point that may be stipulated there, into an attitude of the applicable real item. These transformation data can then be used, e.g., to ascertain the at least one grip point on the item. In a comparable manner, the control data for the gripping device can then also be ascertained from the transformation data and further information regarding an accessibility of the item, for example.

The objects and advantages are furthermore achieved in accordance with the invention by a system for gripping an item, where the system comprises an optical capture device for capturing an image of the item, a data processing device for determining at least one item parameter of the item and/or for ascertaining control data for a gripping device for gripping the item, and an ML model that has been configured using training data generated in accordance with the present disclose, where the system is configured to ascertain control data for a gripping device in accordance with the present disclosure.

In one advantageous embodiment, the data processing device can comprise the ML model, or an ML model in accordance with the present disclosure, for example. The data processing device may be formed and configured as a programmable logic controller, for example, where the ML model can be provided in a central module of the programmable logic controller, for example. Alternatively, the ML model may also be provided in a functional module that is connected to an aforementioned central module of the programmable logic controller via a backplane bus of the programmable logic controller.

To perform the method, the data processing device can comprise an appropriate runtime environment, for example, which is configured, for example, to run software that, when running, results in a method in accordance with disclosed embodiments being implemented.

The data processing device can also comprise multiple components or modules (e.g., comprising one or more controllers, edge devices, PLC modules, computers and/or comparable devices). Such components or modules may then, for example, be connected via an appropriate communication connection, e.g., an Ethernet, an industrial Ethernet, a fieldbus, a backplane bus and/or comparable devices. In another embodiment, this communication connection may furthermore be configured for realtime communication, for example.

In another embodiment of a system in accordance with the disclosed embodiments, the data processing device may be formed and configured as a modular programmable logic controller having a central module and a further module, or can comprise such a programmable logic controller, where the further module furthermore comprises the ML model.

There may furthermore also be provision for the data processing device to comprise a modular programmable logic controller having a central module and a further module, and for the at least one item parameter of the item to furthermore be determined using the further module.

A programmable logic controller (PLC) is a control device that is programmed and used to automatically control or control an installation or machine. Such a PLC may have specific functions, such as flow control, implemented in it, and so in this way both the input signals and the output signals of processes or machines can be controlled. The programmable logic controller is defined in the EN 61131 standard, for example.

A programmable logic controller can be connected to an installation or machine by using both actuators of the installation or machine, which are generally connected to the outputs of the programmable logic controller, and sensors of the installation or machine. In principle, the sensors are situated at the PLC inputs, and provide the programmable logic controller with information about what is happening in the installation or machine. Applicable sensors are, by way of example, light barriers, limit switches, pushbutton switches, incremental transmitters, fill level sensors, temperature sensors. Applicable actuators are, e.g., contactors for switching on electric motors, electrical valves for compressed air or hydraulics, drive control modules, motors, drives.

A PLC can be produced in different ways. That is, it can be implemented as an individual electronic device, as a software emulation, as a “soft” PLC (or “virtual PLC” or PLC application or PLC app), or as a PC expansion card. There are often also modular solutions involving the PLC being assembled from multiple plug-in modules.

A modular programmable logic controller may be configured such that there can be or is provision for multiple modules, there generally being able to be provision for one or more expansion modules besides a so-called central module that is configured to run (execute) a control program, e.g., for controlling a component, machine or installation (or a part thereof). Such expansion modules may be formed and configured as a current/voltage supply, for example, or for inputting and/or outputting signals or data. Furthermore, an expansion module may also be formed as a functional module for undertaking specific tasks (e.g., a counter, a converter, data processing using artificial intelligence methods (comprises, e.g., a neural network or other ML model) and so on).

By way of example, a functional module may also be formed and configured as an AI module for performing actions using artificial intelligence methods. Such a functional module can comprise, for example, a neural network or the ML model or a further ML model in accordance with the present disclosure.

The further module, which comprises the ML model in the presently contemplated embodiment, may then be provided, for example, to perform specific tasks while the method is being performed, e.g., computationally complex subtasks or computationally complex special tasks (such as transformation, and/or use of AI or ML methods). The further module may be specifically configured for this purpose, for example, and/or can also comprise a further program runtime environment for applicable software.

The presently contemplated embodiment further simplifies the system for gripping the item, because the data processing device can be matched specifically to an intended gripping task. In particular, this is possible without needing to change a central method sequence that may take place in a central module of the programmable logic controller, for example. Specific subtasks can then be performed in the further module, which may then be configured differently depending on the exact gripping task.

In another embodiment of a system in accordance the present disclosure, the data processing device can comprise an edge device, or may be formed and configured as an edge device, where the edge device furthermore comprises the ML model.

There may furthermore be provision for the at least one item parameter of the item to be determined using the edge device.

By way of example, an edge device can comprise an application for controlling apparatuses or installations and/or an application for processing, analyzing and/or forwarding data from a control device for an apparatus or installation or data from the apparatus or installation itself. By way of example, such an application may be formed and configured as an application with the functionality of a programmable logic controller. The edge device may be connected to a control device of an apparatus or installation, for example, or directly to an apparatus or installation that is to be controlled. Furthermore, the edge device may be configured such that it is additionally connected to a data network or a cloud, or is configured for connection to an applicable data network or an applicable cloud.

An edge device may furthermore be configured to provide additional functionalities relating to the control of a machine, installation or component (or parts thereof) for example. Such additional functionalities may be, e.g.:
collecting data and transferring them to the cloud, preprocessing, compression, analysis;
analysis e.g. using AI methods, e.g., via a neural network or another ML model. The edge device can comprise, e.g., an ML model, e.g., an ML model in accordance with the present disclosure, for this purpose.

An edge device often has higher computing power compared with a rather conventional industrial control device, such as a controller or a PLC. A result, such an embodiment simplifies and/or speeds up a method in accordance with the disclosed embodiments. In one possible embodiment, a method in accordance with the disclosed embodiments is performed completely on such an edge device.

In an alternative embodiment, particularly computationally intensive and/or complex method steps are implemented on the edge device, for example, while other method steps are implemented on a further component of the data processing device, such as a controller or a programmable logic controller. Computationally intensive and/or complex method steps such as these may be, for example, method steps using machine learning techniques or artificial intelligence, such as the use of one or more ML models in accordance with the present disclosure.

Such a system having an edge device may furthermore be configured such that the at least one item parameter of the item is determined using the ML model, where the edge device comprises the ML model.

Furthermore, such a system having an edge device may also be configured such that the control data for the gripping device are ascertained using the ML model, where the device comprises the ML model.

An exemplary possible embodiment of a method and/or an apparatus in accordance with the present disclosure is presented below.

This exemplary embodiment is based on the problem that in many manufacturing processes parts are made available via “drawer-containers”as a transport system. Such parts can come from external suppliers, for example, or can come from an upstream internal production process. By way of example, the further manufacturing process requires these parts to be isolated and to be individually manipulated or transported in a specific manner. Specifically for manufacturing methods in which this further handling is performed by robot arms, precise information regarding the attitude and orientation of the isolated parts is required. However, the attitude and position of the parts in such drawer-containers is totally random and be cannot stipulated in a predefined manner. These data therefore need to be ascertained dynamically in order to be able to successfully grip and transport these parts using a robot arm, for example.

By way of example, as part of this exemplary embodiment, an illustrative method and system for gripping an item in accordance with the present disclosure may be configured, e.g., such that the system can locate objects or parts for which a 3D model of the object or part is available. Such a 3D model may have been created by 3D CAD software, for example. By way of example, such a method can be implemented on various hardware devices, for example, a programmable logic controller, a modular programmable logic controller, an edge device or using computing capacity in a cloud, for example, in order to perform the applicable image processing. A programmable logic controller in this instance may be configured, for example, such that method steps are performed using artificial intelligence or machine learning techniques in a specific functional module for the programmable logic controller for performing artificial intelligence methods. Such modules can comprise a neural network, for example.

The illustrative system described below can recognize the 6D orientation of any items, e.g., using an applicable 3D model of the item, with the result that the item can reliably be gripped at a grip point specified in the 3D model. This permits the system to supply appropriate supply parts to a specific production step, for example, with high repeatable accuracy.

A general design of a system for performing such a method can comprise the components cited below, for example:
a.) A transport system for parts to be processed having a planar surface, optionally having a vibration isolation device;
b.) A robot arm for gripping the parts to be processed;
c.) A camera for capturing image data from the parts to be processed on the transport system for an applicable camera controller;
d.) A programmable logic controller (PLC) in order to provide grip coordinates of each of the supply parts and to transfer said coordinates to the robot;
e.) A camera controller for identifying the parts (classification), for determining the orientation thereof (detection/segmentation) and for ascertaining the grip coordinates.

By way of example, an illustrative system such as this can thus comprise: the PLC, the camera controller, the camera, software running on the respective components, and further software that generates input values for the software.

After an image containing multiple parts has been captured, the system described by way of illustration is configured to recognize the parts, and to then select a specific part to be gripped and to determine the grip points for this part that is to be gripped. For this purpose, the software and the further software implement the following steps, for example:

1.) Image segmentation: in a first step, the image is segmented using an AI model (“M-Seg”). This segmentation AI model M-Seg is an example of a detection ML model in accordance with the present disclosure. It is assumed in this instance that each of the parts is considered in isolation as if it were situated individually or singly on the setdown surface or the supply device. Thereafter, for each of the parts, a rectangular virtual bounding frame (location in X, Y) is ascertained, a type of the object is determined and a position/scaling in the X, Y direction is computed. The position in this instance corresponds to the approximate orientation in the rotation dimension of the 6D space, based on the possible stable attitudes of the parts, as are explained below. The selected part, in particular, for example, the associated virtual bounding frame, then defines the region of interest (ROI) to which the subsequent steps are applied.

2.) In a further, optional step, the angle of rotation of the selected part with reference to the setdown surface is computed. This is performed using a regression and/or classification AI model (“M-RotEst”). M-RotEst is an example of an angle detection ML model in accordance with the present disclosure.

3.) In a next step, a third AI model (“M (parts ID, adopted stable attitude, angle of rotation)”) is applied to the ROI that contains the selected part. The variables already determined in the preceding steps: type of the part (parts ID), adopted stable attitude, and the ascertained angle of rotation of the part, are used as input variables. A deep neural network, a random forest model or a comparable ML model can be used for this third AI model, for example. Furthermore, a 3D model of the selected part is selected from an applicable database, for example. In a further step, an image evaluation method, such as SURF, SIFT or BRISK, is then applied to the ROI. The recognized features of the 3D model of the selected part and in the captured image of the part are compared. This last step yields the transformation data between the 3D model of the selected part and the selected part in the captured camera image in reality. These transformation data can then be used to transform grip points denoted in the 3D model into the real space such that the coordinates of the grip points for the selected part are then available. This third AI model M (parts ID, adopted stable attitude, angle of rotation) is an example of a transformation ML model in accordance with the present disclosure.

The text below describes how the aforementioned software or the cited ML models (e.g., M-Seg, M-RotEst and M (parts ID, adopted stable attitude, angle of rotation)) can be configured or trained to perform the discloses embodiments of the method.

This involves providing a 3D model of the part to be gripped as an input, possible grip points for the part being specified or denoted in the 3D model.

Furthermore, a first step then comprises determining possible stable attitudes of the part on a planar surface. One such possible stable attitude is an attitude in which the object is balanced and does not fall over. In the case of a coin, this is also an attitude in which the coin is standing on its edge, for example.

These possible stable attitudes can be ascertained, for example, by dropping the items onto a planar surface under a wide variety of initial conditions. This can occur in reality or in a corresponding physical simulation using a 3D model of the part. Both in the simulation and in reality, a period of time is then waited until the part is no longer moving. The position that is then attained is considered to be a stable attitude, and recorded as such. Another option for ascertaining possible stable attitudes is to ascertain those positions in which the selected part touches a planar surface at (at least) three points, in which case the object does not penetrate the surface at any other point. The stable attitudes ascertained in one of the manners described are then each assigned a unique identifier.

Subsequently, training data are then generated for the segmentation ML model (M-Seg). The training data consist of a set of images containing captured items, annotated or labelled with the respective location of the item, ID information or a type of the item, and an accordingly adopted stable attitude. By way of example, these data can be generated by positioning various objects in corresponding stable attitudes in the real world. Alternatively, 3D models of the objects can also be virtually arranged in respective stable positions in ray tracer software or a games engine, in which case corresponding images of these items are subsequently produced artificially.

Thereafter, labels are produced for the applicable images of the objects. The label for each of the objects consists of a rectangular virtual bounding frame (x1, y1, x2, y2), the object type and an identifier for the adopted stable attitude.

If the optional angle detection model M-RotEst is used, then the label assigned is furthermore the angle of rotation of the selected part with reference to a surface normal of the setdown surface. When a simulation is used to generate such data, for example, using a ray tracer engine, these data for labelling the captured images can be generated automatically.

All of these data generated in such a way can then be used to train a deep neural network, for example, where for example standard architectures such as YOLO can be used for the model M-Seg and a convolutional neural network can be used for the regression or the regression model.

In a subsequent step, reference images of the respective parts in the respective stable positions are then again produced. This can again be achieved using real objects or be produced via the virtual simulation. Using real objects has the disadvantage that the labelling needs to be performed manually. When virtual 3D models are used, the data required for labelling can be generated automatically and the labelling can therefore also be performed automatically. Furthermore, the transformation data can also be ascertained more accurately if the images are produced based on a physical simulation using 3D models.

The generated transformation data then permit the methods in accordance with the disclosed embodiments to be used to transform grip points denoted in the 3D model of a specific part into the coordinates of corresponding grip points on a real captured part so that a gripping device can use these coordinates to grip the real part at the appropriate grip points.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

The present invention is explained in more detail below by way of illustration with reference to the appended figures, in which:

FIG. 1 shows an exemplary system for gripping an item in accordance with the invention;

FIG. 2 shows an exemplary 3D model with grip points and depicted stable attitudes in accordance with the invention;

FIG. 3 shows exemplary methods for ascertaining stable attitudes of an item in accordance with the invention;

FIG. 4 shows exemplary methods for training an ML model in accordance with the invention;

FIG. 5 shows exemplary methods for generating training data for an ML model in accordance with the invention;

FIG. 6 shows an exemplary method for gripping an item in accordance with the invention;

FIG. 7 shows an exemplary captured camera image of items, including a depiction of the associated 3D models in accordance with the invention;

FIG. 8 shows a second exemplary of a system for gripping an item in accordance with an embodiment of the invention; and

FIG. 9 shows a third exemplary system for gripping an item in accordance with an embodiment of the invention.

### DETAILED DESCRIPTION OF THE EXEMPLARY EMBODIMENTS

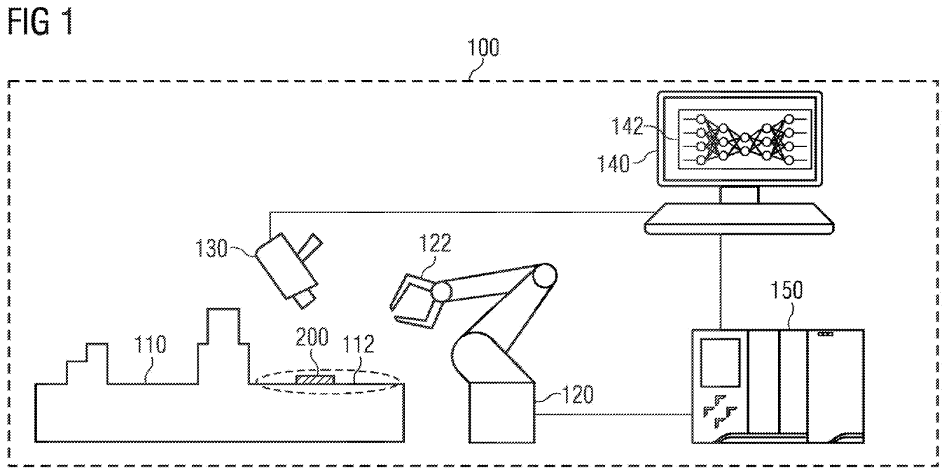

FIG. 1 shows a gripping system 100 as an exemplary embodiment of a system in accordance with the present disclosure. This illustrative gripping system 100 is configured to detect, select and grip and transport items 200 on a transport device 110.

To this end, FIG. 1 shows a cuboidal grippable object 200 that is transported within a transport device 110 to a planar setdown surface 112 and set down there. Furthermore, there is provision for a camera 130 for capturing the setdown surface 112 with the grippable object 200, where the camera is connected to an industrial PC 140. The industrial PC 140 comprises image evaluation software, which comprises a neural network 142. This image evaluation software with the neural network 142 is used to evaluate the images captured by the camera 130 such that the grippable object 200 and other possible objects are detected and data for grip points for gripping this object are ascertained using a method that is described in more detail below.

These data for the grip points for gripping the object 200 are then transferred from the industrial PC to a modular programmable logic controller (PLC) 150. There, these data are processed further and then transferred to a robot 120 having a gripper 122. The robot 120 then controls its gripper 122 using these data such that the gripper 122 grips the object 200 at the grip points provided for that purpose and transports it to a further production step, which is not depicted in FIG. 1.

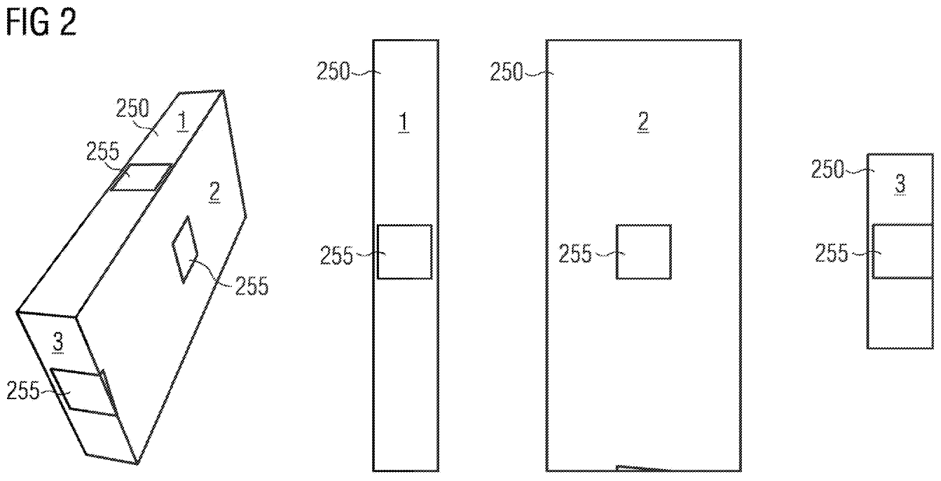

FIG. 2 shows a 3D model 250 of the cuboidal grippable object 200. The 3D model 250 of the cuboidal grippable object 200 in FIG. 2 is depicted both in a perspective view (far left in FIG. 2) and in its three stable attitudes in accordance with the present disclosure. Three of the six sides of the 3D model 250 of the cuboid 200 are furthermore denoted by corresponding numerals in FIG. 2. The stable attitudes 1, 2 and 3 of the 3D model 250 are each depicted in a view from above.

Furthermore, grip points 255 each provided for gripping the applicable item are depicted as black squares in the 3D model 250. The grip points 255 are points at which an applicable cuboid 200 can advantageously be gripped by a gripping device 120, 122. The 3D model 250 was created by an applicable 3D CAD program. The applicable model grip points 255 in the 3D model 250 were denoted within this program.

The “stable attitude 1” depicted in FIG. 2 shows an attitude of the 3D model 250 in which the model comes to rest on the narrow long side and the narrow long side that is parallel thereto, which is denoted by a numeral 1 in FIG. 2, points upward. In the “stable attitude 2” depicted in FIG. 2, the wide long side that is denoted by a numeral 2 in FIG. 2 points upward. Accordingly, the “stable attitude 3” depicted in FIG. 2 shows an attitude in which the short narrow side of the 3D model 250 that is denoted by a numeral 3 in FIG. 2 points upward.

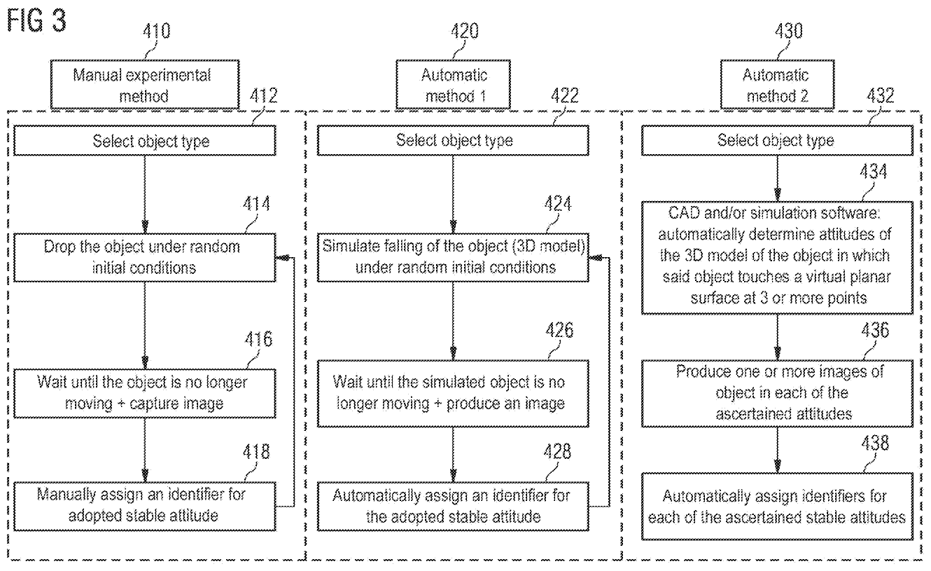

The stable attitudes depicted in FIG. 2 may have been ascertained using a method in accordance with the present disclosure. Some examples of such a method are explained in more detail with reference to FIG. 3 that follows.

FIG. 3 shows three illustrative methods 410, 420, 430 for ascertaining one or more stable attitudes of an object or item.

In a first, manual method 410, a first step 412 comprises selecting a specific object type for which one or more stable attitudes are meant to be ascertained.

In a next step 414, this object is dropped onto a planar surface under random initial conditions. The random initial conditions comprise a randomly ascertained height above the planar surface and an initial velocity for the selected object with arbitrary direction and velocity.

Thereafter, a step 416 comprises waiting until the dropped object is no longer moving. Once the object has come to rest, an image of the object on the planar surface is captured, for example, using a camera.

In a next step 418, the stable position adopted by the object on the planar surface is then identified and an identifier unique to the adopted stable position is ascertained. This identifier, which is unique to the adopted stable position, is then assigned to the captured image.

A thus ascertained combination of a captured image with a unique identifier for the stable attitude adopted by the object in the image can then be used for later comparable measurements, for example, in order to assign accordingly unique identifiers to stable positions. As such, such image-identifier combinations can be used to build a database for stable attitudes of objects, for example. Furthermore, such an image-identifier combination can be used to train an ML model in accordance with the present disclosure.

In a further advantageous embodiment, after method step 418, method step 414 is performed again, for example, using the same object and different initial conditions. In this way, a new image-identifier combination is then again produced, which can then be handled as already described above. This is denoted by an arrow between method steps 418 and 414 in FIG. 3. In this way, the method can be performed until there are enough image-identifier combinations for a database or for training an applicable ML model, for example. This may be the case, for example, if enough image-identifier combinations are available for each of the possible objects and each of the possible stable attitudes of such objects.

FIG. 3 furthermore shows a first automatic method 420 likewise for ascertaining stable attitudes of one or more objects. Here, a first step 422 also comprises selecting an object for which accordingly stable attitudes are also meant to be determined. An applicable 3D model is then selected for this object. Such 3D models can be created or may have been created using applicable 3D CAD programs, for example.

In a next step 424, the falling of such an object onto a planar surface is then simulated, using the 3D model of the object, onto a virtual surface using a simulation environment with a physical simulation (for example, with a game engine). The initial conditions, for example, in terms of velocity and direction, can be chosen randomly in this instance.

Next, a step 426 comprises continuing the simulation until the simulated object is no longer moving within the framework of normal measurement accuracy. The simulation environment is then used to produce an image of the item's 3D model that has come to rest on the virtual planar surface. The image is produced such that it corresponds to a camera shot of a real object, corresponding to the 3D model, on a real planar surface, corresponding to the virtual surface.

Thereafter, the next step 428 comprises assigning a unique identifier for the stable attitude adopted by the 3D model in the image to this created or produced image.

As in the example above, this image-identifier combination can then be used to build an applicable database or to train an applicable ML model.

In one advantageous embodiment, the method can then be performed repeatedly by virtue of method step 428 then again being followed by method step 424. In this subsequent step 424, the falling of a 3D model is then simulated, for example, under different initial conditions. This is depicted in FIG. 3 by a corresponding connecting arrow between method step 428 and method step 424.

In this way, it is again possible, as already described above, to produce as many image-identifier combinations as are necessary to build an applicable database or to train an applicable ML model.

Furthermore, FIG. 3 shows a second automatic method 430 for ascertaining stable object attitudes. Here, a first step 432 comprises selecting an object for which stable object attitudes are also subsequently determined.

This second automatic method again uses a 3D model of the selected object type. Here, a next method step 434 comprises using applicable simulation or CAD software to ascertain those attitudes of the selected 3D model on a virtual surface in which the 3D model touches the virtual planar surface at three or more points without the 3D model penetrating this planar surface at further points.

A next step 436 then comprises producing one or more images of the 3D model on the virtual planar surface for each of these ascertained attitudes of the 3D model on the virtual planar surface in a comparable manner to the first automatic method 420. In the case of multiple images, different virtual camera positions can be used for each of the images.

In a next method step 438, a unique identifier for the stable attitude adopted by the object in the respective images is then assigned to each of the corresponding created images.

These identifier-image combinations can then again be used to build an applicable database for stable attitudes of objects and/or to train one or more applicable ML models.

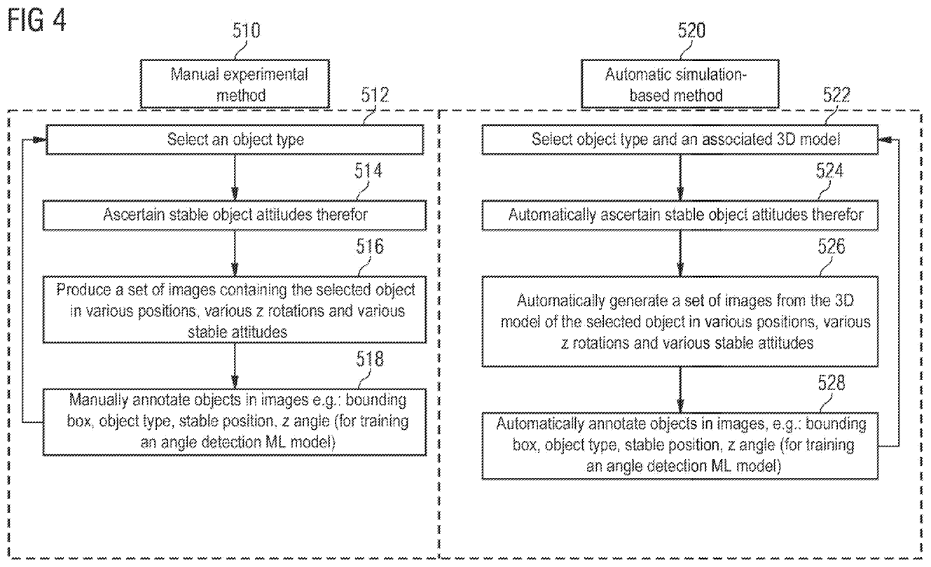

FIG. 4 shows two exemplary methods 510, 520 for generating training data for a detection ML model and/or an angle detection ML model.

The first method 510, depicted on the left in FIG. 4, is provided for manually or semiautomatedly ascertaining training data for a detection ML model and/or an angle detection ML model. A first step 512 comprises selecting a specific object type for which applicable training data are meant to be generated.

In a further step 514, stable object attitudes are ascertained for this object type on a planar surface. By way of example, methods in accordance with the present disclosure can be used.

In a subsequent work step 516, a plurality of images are produced using the selected object in various positions, various stable attitudes and at various angles of rotation about a surface normal of the planar surface or, e.g., are selected from a database or image collection.

In a subsequent work step 518, the respective images are assigned identifier data for the object, for example, data relating to a virtual frame around the object, an object type, an identifier for the adopted stable attitude and/or a location. If training data are generated for an angle detection ML model, then the identifier data furthermore also comprise an angle of rotation.

Thereafter, the same method steps are again performed with a further object type beginning with method step 512. This loop is repeated until training data have been generated for all those objects that are required for using the applicable ML model.

The automatic, simulation-based method 520 depicted on the right-hand side of FIG. 4 again begins, in a first method step 522, with selection of an object type and an accordingly associated 3D model for this object type. The 3D model may be configured in accordance with the present disclosure, for example.

Thereafter, the next method step 524 again comprises automatically ascertaining the stable object attitudes using the 3D model of the selected object type. This automatic ascertainment can occur in accordance with the present disclosure, for example.

In a next method step 526, a set of images is automatically produced using the 3D model of the selected object type in/at various positions, stable attitudes and angles of rotation. By way of example, these images can again be produced in accordance with the present disclosure, for example, using an applicable ray tracer engine.

In a next method step 528, the images produced are then automatically annotated or labelled with applicable identification data. Such identification data are, for example, information regarding a virtual frame around the depicted object, an object type, an identifier regarding a stable attitude of the object and/or a position of the object. If the training data are provided for training an angle detection ML model, then the identification data furthermore comprise an angle of rotation. The identification data can be annotated or labelled automatically, because the virtual production of the images using a simulation environment and an applicable ray tracer engine means that these data are already known when the image is produced.

Thereafter, the method steps are performed, beginning with method step 522, for a further object type. This loop is performed until training data have been generated for all those objects that are required for using the applicable ML model.

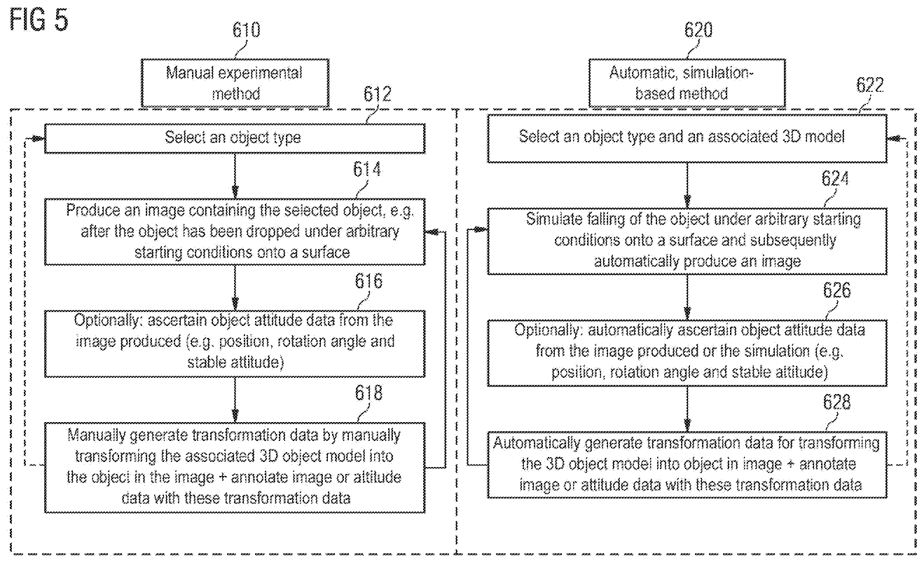

FIG. 5 shows two methods 610, 620, which are exemplary methods for generating training data for a transformation ML model.

A first manual method 610 is depicted on the left-hand side of FIG. 5.

In a first work step 612, a specific object type is again selected, for which applicable training data are then generated.

In a second work step 614, an image is then produced using the selected object type, e.g., after the selected object has been dropped onto a planar surface under arbitrary initial conditions (e.g., in terms of height and starting velocity vector).

In a next, optional step 616, object attitude data are then ascertained from the image produced. Such object attitude data may be, or comprise, for example, a position of the object, an identifier for the object, information regarding a virtual bounding frame around the object, an angle of rotation and/or an adopted stable attitude.

Subsequently, a next step 618 then comprises determining transformation data for transforming a 3D model of the selected object into the attitude of the model in the image produced. This can be achieved, for example, such that the captured image is overlaid, for example, on a computer screen, with a depiction of the 3D model and manual transformation actions by a user transform, or rotate and shift and escalate, the 3D model image of the object such that it matches the object depicted in the image that is produced. The transformation operations used in the process can then be used to ascertain the desired transformation data in a manner that is known to a person skilled in the art.

Thereafter, these transformation data are then assigned, for example, to the image produced or to the ascertained object attitude data. These annotated or labelled images, or annotated or labelled attitude data, can then be used to train an applicable transformation ML model.

The method steps are subsequently repeated, beginning with method step 614, until enough training data have been generated for the selected object type. This loop is symbolized by a corresponding arrow on the right-hand side of the depicted manual experimental method 610.

If enough training data have been generated for a specific object, then the last method step 618 performed to annotate an image, or attitude data, is followed by the manual method 610 being begun again at the first method step 612 to select a new object type, after which applicable training data are ascertained for this further object type. This loop is symbolized by a dashed arrow on the left-hand side of the manual method 610 depicted in FIG. 5.

The above-depicted sequence for the manual method 610 is repeated until enough training data have been ascertained for all relevant object types.

The right-hand side of FIG. 5 shows an illustrative automatic method 620 that can be used to generate training data for a transformation ML model in an automated and simulation-based manner.

Here, a first method step 622 also comprises ascertaining a specific object type and an applicable 3D model therefor.

Thereafter, a next method step 624 comprises automatically producing an image of the selected 3D model in an arbitrary position, with an arbitrary angle of rotation and in an arbitrary stable attitude. By way of example, this can be achieved via a physical simulation in which the falling of an applicable object onto a planar surface is simulated under arbitrary starting conditions (e.g., in terms of height and velocity vector), and then an applicable ray tracer engine is used to produce an image of the item after said item has come to rest again in the simulation. This production of an image may be configured in accordance with the present disclosure, for example.

If the stable attitudes of the item are known, then the images can, e.g., also be produced by depicting or rendering the 3D model of the item with various positions, angles of rotation and stable attitudes in a particular image, e.g., using an applicable 3D modeling or 3D CAD tool.

In a next optional method step 626, object attitude data are automatically taken from the image produced or directly from the applicable simulation environment or the applicable 3D modeling or 3D CAD tool. Such object attitude data can again comprise, for example, a position, information regarding a virtual bounding frame around the object, an angle of rotation and/or an identifier for an adopted stable attitude of the object.

In a subsequent method step 628, transformation data for transforming the 3D model of the object into the object in the simulation environment, or the object depicted in the image produced, are then automatically generated. This can be achieved, for example, by importing the 3D model of the object into the simulation environment and subsequent automatically ascertained or ascertainable transformation operations such that the imported 3D model of the object is converted into the object on the planar surface in the adopted stable attitude. This sequence of transformation operations can then already represent the applicable transformation data. Furthermore, this sequence of transformation operations can alternatively be converted into the transformation data in a manner known to a person skilled in the art. The image produced or the attitude data ascertained therefor is/are then annotated or labelled with these corresponding transformation data, for example. The thus labelled images or attitude data can then be used as training data for an applicable transformation ML model.

As already mentioned in connection with the manual method 610 in FIG. 5, here a first method loop back to method step 624 can first also produce further images for the selected object type and thus also further training data for this object type for a transformation ML model. This first loop is denoted in FIG. 5 by an arrow on the left-hand side of the method sequence of the automatic method 620.

If enough training data have been generated for a specific object type, then a second overlaid method loop, again beginning with the first method step 622, is used to select a new object type and thereafter the above-explained method is performed for this further object type. This second overlaid method loop is depicted in FIG. 5 on the right-hand hand side of the depiction of the automatic method 620 by a corresponding dashed arrow from the last method step 628 to the first method step 622.

The entire automatic method 620, as depicted above, is then performed until enough training data to train an applicable transformation ML model are available for all the required object types.

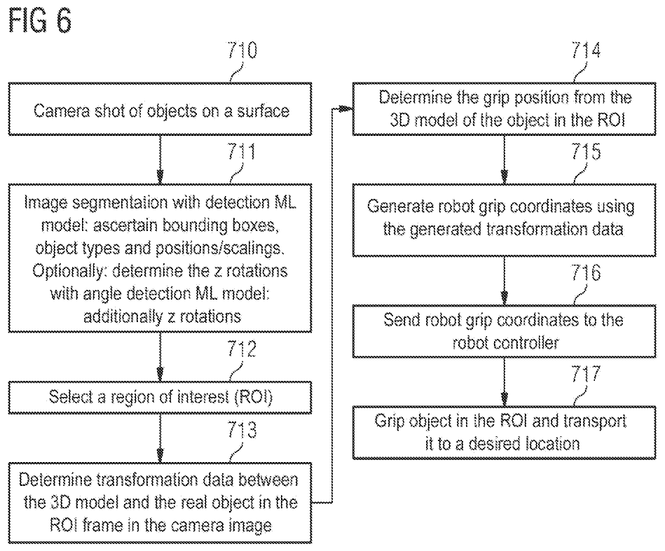

FIG. 6 shows an exemplary method sequence for gripping an object from a surface using a detection ML model, or an angle detection ML model, and a transformation ML model in accordance with the present disclosure.

The method depicted in FIG. 6 is explained in more detail below using the exemplary system depicted in FIG. 1.

In a first method step 710, the camera 130 takes a camera shot of the cuboid 200 that is on the setdown surface 112.

This camera image is transferred in the next method step 711 to the industrial PC 140, on which applicable image evaluation software comprising an applicable detection ML model or an applicable angle detection ML model is implemented. The neural network 142 depicted in FIG. 1 is an example of such a detection ML model or such an angle detection ML model.

In method step 711, the detection ML model is used to determine a virtual bounding frame (a “bounding box”) around the represented cuboid 200, and to determine an object type for the captured cuboid 200 and its position and scaling in the recorded image and a stable position adopted therein. This ascertainment of the parameters may be configured as explained in more detail in the present disclosure, for example. Optionally, an angle detection ML model can also be used, in which case an angle of rotation about a surface normal of the setdown surface 112 is also ascertained as an additional parameter. This ascertainment may also be configured in accordance with the present disclosure, for example.

If multiple objects are depicted in the captured image, then method step 711 is performed for each of the depicted objects.

In a further method step 712, the virtual bounding frame that contains the object that is meant to be gripped by the robot 120 is selected, for example. In the present example, the selected bounding frame corresponds to the one around the cuboid 200.

Thereafter, a next method step 713 comprises using a transformation ML model accordingly trained for this application to generate transformation data for transforming a 3D model 250 for the cuboid 200 into the cuboid 200 that is on the setdown surface 112. This involves, for example, inputting characteristic attitude data relating to the cuboid 200, such as its position, information about the virtual bounding frame around the cuboid, the adopted stable attitude, an angle of rotation with reference to a surface normal of the setdown surface 112 or comparable attitude data, into the transformation ML model. The model then delivers the applicable transformation data for transforming the 3D model 250 of the cuboid 200 into the cuboid 200 that is on the setdown surface 112.

Thereafter, a next method step 714 comprises determining coordinates of the grip points 255 captured in the 3D model 250 of the cuboid 200.

Thereafter, the transformation data generated in method step 713 are then applied, in a further method step 715, to the coordinates of the model grip points 255 that have been ascertained in method step 714, in order to then determine therefrom specific robot grip coordinates for gripping the cuboid 200 on the setdown surface 112. The applicable robot grip coordinates are configured such that the gripper 122 of the robot 120 takes hold of the cuboid 200 at one or more grip points, where these grip points correspond to model grip points 255 in the 3D model 250 of the cuboid 200.

While method steps 711 to 715 are taking place in the industrial PC 140, for example, the robot grip coordinates generated in method step 715 are then transferred from the industrial PC 140 to the PLC 150 in a next method step 716.

In a final method step 717, these data are subsequently converted by the PLC 150 into applicable control data for the robot 120 and transmitted to the robot 120. The robot 120 then grips the cuboid 200 at the computed grip points to subsequently transport it to a desired setdown location.

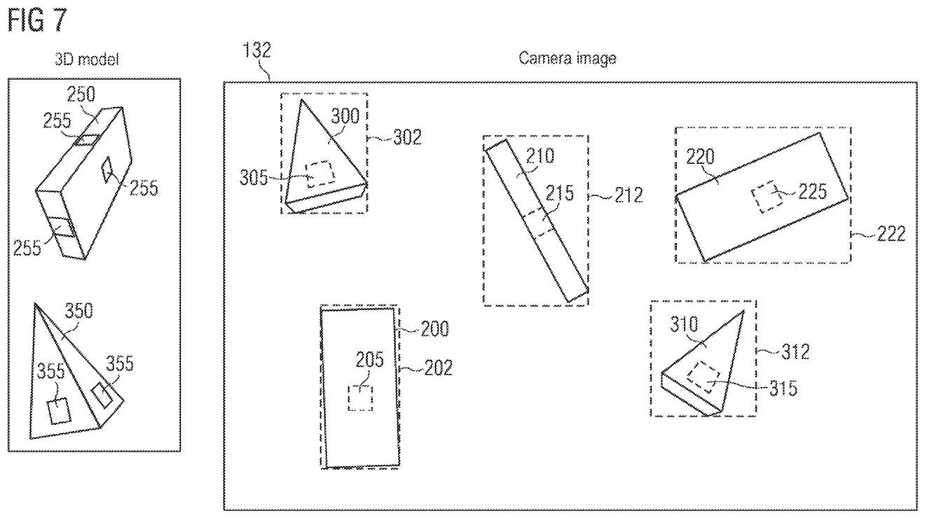

The left-hand side of FIG. 7 shows two 3D models 250, 350, where a 3D model 350 of a pyramid furthermore is also depicted in addition to the 3D model 250 of the cuboid 200 already depicted in FIG. 2. Applicable model grip points 255 are again denoted in the 3D model 250 of the cuboid 200, which denote suitable points on the corresponding cuboid 200 at which a gripper for gripping the cuboid 200 can advantageously attach. Accordingly, model grip points 355 are denoted in the 3D model 350 of the pyramid for gripping a corresponding pyramid.

By way of illustration, the right-hand side of FIG. 7 shows a camera image 132 in which cuboids 200, 210, 220 and pyramids 300, 310 that are on an applicable planar surface have been captured. The three depicted cuboids 200, 210, 220 correspond to the 3D model 250 of the cuboid that is depicted on the left-hand side of FIG. 7. The two pyramids 300, 310 correspond to the 3D model 350 of the pyramid that is depicted on the left-hand side of FIG. 7.

A first cuboid 200 depicted in the camera image 132 is in the second stable attitude for this cuboid 200, as was illustrated in the explanations relating to FIG. 2. In this second stable attitude, the wide long side denoted by the numeral 2 in FIG. 2 points upward. Furthermore, an applicable grip point 205 on the cuboid 200 is denoted in the camera image 122, where the grip point corresponds to the model grip point 255 in the second stable attitude that is depicted in FIG. 2.

A method in accordance with the present disclosure can then be used, for example, to compute transformation data that can be used to convert the parameters for the applicable model grip point 255 into coordinates for the grip point 205 on the cuboid 200 in the camera image 132. These transformation data can then be used, for example, to ascertain control data for a robot so that said robot can use a suction gripper, for example, to take hold of the cuboid 200 at the grip point 205 and therefore transport it.

Furthermore, the camera image 132 shows a virtual bounding frame 202 around the depicted cuboid 200. By way of example, this virtual bounding frame 202 can be used to define an applicable region of interest (ROI) for this cuboid 200. Furthermore, the data relating to this virtual bounding frame 202 can be used to ascertain further characteristic variables for the cuboid, such as a position, a scaling factor or an estimate of an angle of rotation and/or a stable attitude, for the depicted cuboid 200.

In a comparable manner, FIG. 7 shows a second cuboid 210, which is in a first stable attitude, as was explained in FIG. 2. The narrow long side of the cuboid 210, which is denoted by the numeral 1 in FIG. 2, points upward. An applicable cuboid grip point 215 is again depicted in the camera image 132, where the grip point corresponds to the model grip point 255 that corresponds in the image of the view of the stable attitude 1 of the 3D model 250 of the cuboid in FIG. 2. Furthermore, here too, a virtual bounding frame 212 is depicted around the second cuboid 210.

Furthermore, FIG. 7 shows a third cuboid 220 in the camera image 132, where cuboid is again in the second stable attitude depicted in FIG. 2. Here, an applicable grip point 225 is again also depicted, which corresponds to the model grip point 255 in the second stable attitude that is depicted in FIG. 2. The third cuboid 220 also has an associated corresponding virtual bounding frame 222 that is depicted in the camera image 132.

Accordingly, the camera image furthermore shows a first pyramid 300 having a grip point 305, which is visible in the applicable stable attitude and corresponds to one of the pyramid model grip points 355. This first pyramid 300 also has a corresponding virtual bounding frame 302 depicted around it, which can be used, for example, to select the pyramid for subsequent gripping at the grip point 305.

The camera image 132 furthermore shows a second pyramid 310 in a stable attitude for such a pyramid 300, 310. A grip point 315 is also depicted on this second pyramid 310 captured in the camera image 132, where the grip point corresponds to one of the pyramid model grip points 355. A corresponding virtual bounding frame 312 is also depicted for this second pyramid 310 in the camera image 132.

By way of example, such a camera image 132 could be captured when there are three cuboids 200, 210, 220 according to the 3D model 250 of these cuboids 200, 210, 220, and two pyramids 300, 310 according to the 3D model 350 of these pyramids 300, 310, on the setdown surface 112 of the transport device 110 depicted in FIG. 1.

An image evaluation method in accordance with the present disclosure can then be used to ascertain, for example, the virtual bounding frames 202, 212, 222, 302, 312 and also the respective positions, stable attitudes and angles of rotation of the depicted items 200, 210, 220, 300, 310. By way of example, the first cuboid 200 can be selected in an applicable selection step.

A method in accordance with the present disclosure can then be used to ascertain from the ascertained position data and parameters of the first cuboid 200 in the camera image 132 transformation data that can be used to transform the 3D model 250 of the cuboid 200 into the cuboid that is in the camera image 132 in reality. These transformation data can then be used to convert the cuboid model grip points 255 into coordinates of the grip points 205 on the cuboid 200 in the camera image 132. These coordinates for the grip points 205 on the selected cuboid 200 can then be used to ascertain robot data for actuating a robot that, for example, has a suction gripper. This suction gripper can then be used to take hold of the cuboid 200 at the cuboid grip points 205 and to transport it.

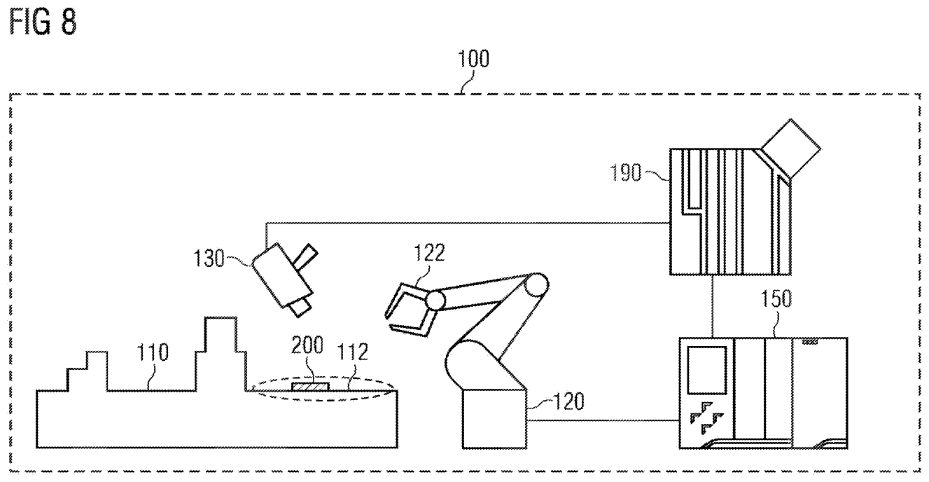

FIG. 8 shows a variation of the gripping system 100 already depicted in FIG. 1. In the gripping system 100 depicted in FIG. 8, the industrial PC 140 for image evaluation depicted in FIG. 1 is replaced with an edge device 190, which is likewise configured to, at least among other things, evaluate images from the camera 130. By way of example, the edge device may be configured in accordance with the present disclosure and, in addition to being coupled to the PLC 150, for example, may also be connected to a cloud, which is not depicted in FIG. 8. There may furthermore be provision for the image evaluation method for evaluating the images, or at least parts thereof, captured by the camera 130 to occur on this cloud.

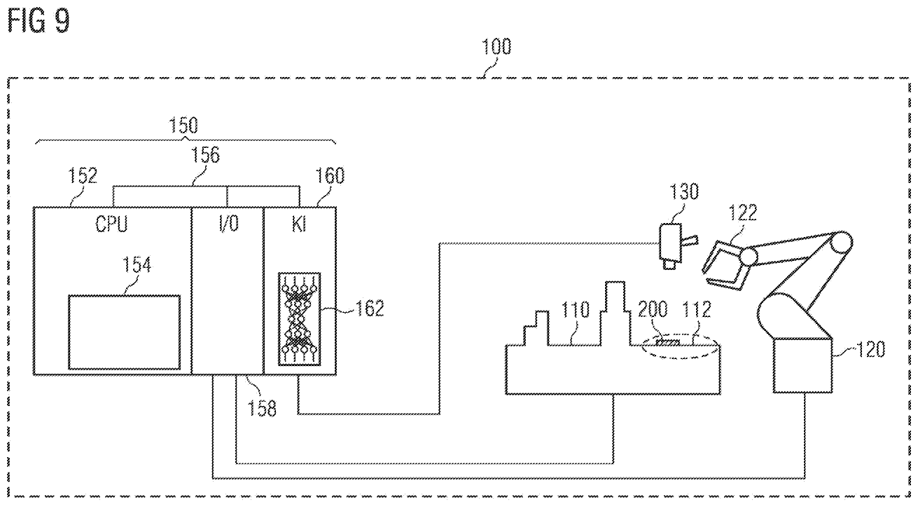

FIG. 9 depicts another variation of the gripping systems 100 depicted in FIGS. 1 and 8, where the images captured by the camera 130 are evaluated in the PLC 150 in the gripping system 100 depicted in FIG. 9. To this end, the PLC 150 comprises a central control assembly 152 that has a runtime environment 154 for running or executing an applicable control program, among other things for actuating the transport device 110 and the robot 120. Furthermore, the PLC 150 comprises an input/output assembly 158 that is used by the PLC 150 to communicate with the transport device 110 and the robot 120. The PLC 150 furthermore comprises a functional module 160 for running or executing an image evaluation method for evaluating images from the camera 130, where the functional module 160 comprises a neural network 162 that is an exemplary embodiment of a detection ML model in accordance with the present disclosure, an angle detection ML model in accordance with the present disclosure and/or a transformation ML model in accordance with the present disclosure, for example.

The central module 152, the input/output module 158 and the functional module 160 of the PLC 150 are coupled to one another via an internal backplane bus 156. The communication between these modules 152, 158, 160 occurs via this backplane bus 156, for example.

The PLC 150 may be configured, for example, such that a method in accordance with the present disclosure involves all those work steps that use an ML model implemented in the functional module 160 of the PLC 150, while all other work steps in the method are implemented by a control program running or executing in the runtime environment 154 of the central module 152.

Alternatively, the PLC 150 may also be configured, for example, such that a method in accordance with the present disclosure involves all work steps related to the evaluation of images, in particular images from the camera 130, occurring in the functional module 160, while the work steps for controlling the transport device 110 and the robot 120 are implemented by a control program running or executing in the runtime environment 154 of the central control assembly 152.

In this way, the PLC 150 can be configured very effectively to run a method in accordance with the present disclosure, because computationally intensive special tasks, such as handling the ML models or evaluating images, can be relocated to the specific functional module 160, and all other method steps can occur in the central module 152.

Thus, while there have been shown, described and pointed out fundamental novel features of the invention as applied to a preferred embodiment thereof, it will be understood that various omissions and substitutions and changes in the form and details of the methods described and the devices illustrated, and in their operation, may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

1. A method for generating training data for an ML model (142, 162 ,
wherein the training data are designed and configured to configure the ML model (142, 162) by using a machine learning method,
and wherein in particular the ML model (142, 162) is designed and configured to be used as part of a method for ascertaining control data for a gripping device (120, 122) for gripping an item (200, 210, 220, 300, 310),
characterized by the method steps of:
selecting an item (200, 210, 220, 300, 310),
selecting starting data relating to the item (200, 210, 220, 300, 310) above a planar surface (112),
producing a falling motion for the item (200, 210, 220, 300, 310) in the direction of the planar surface (112) beginning with the starting data,
capturing an image (132) of the item (200, 210, 220, 300, 310) after a motion of the item (200, 210, 220, 300, 310) has stopped on the planar surface (112),
assigning an identifier to the captured image (132), the identifier comprising ID information for a stable attitude adopted by the item (200, 210, 220, 300, 310), the stable attitude adopted by the item being designed and configured in such a way that all of those attitude data relating to the item that can be translated into one another by way of a shift and/or a rotation about a surface normal of the planar surface are assigned to this adopted stable attitude,
storing the training data comprising the captured image and the identifier assigned to said image.

2. A method for generating training data for an ML model (142, 162),
wherein the training data are designed and configured to configure the ML model (142, 162) by using a machine learning method,
and wherein in particular the ML model (142, 162) is designed and configured to be used as part of a method for ascertaining control data for a gripping device (120, 122) for gripping an item (200, 210, 220, 300, 310),
characterized by the method steps of
selecting a 3D model of an item (250, 350),
selecting starting data relating to the 3D model of the item (250, 350) above a virtual planar surface,
simulating a falling motion for the 3D model of the item (250, 350) in the direction of the virtual planar surface beginning with the starting data,
creating an image (132) of the 3D model of the item (250, 350) after the simulated motion of the 3D model of the item (250, 350) has stopped on the virtual planar surface,
assigning an identifier to the created image (132), the identifier comprising ID information for a stable attitude adopted by the 3D model of the item (250, 350), the stable attitude adopted by the item being designed and configured in such a way that all of those attitude data relating to the item that can be translated into one another by way of a shift and/or a rotation about a surface normal of the virtual planar surface are assigned to this adopted stable attitude,
storing the training data comprising the created image and the identifier assigned to said image.

3. The use of training data generated as claimed in claim 1 or 2 for training the ML model (142, 162).

4. The ML model as claimed in claim 1 or 2,
characterized in that the ML model (142, 162) has been trained using training data generated as claimed in claim 1 or 2.

5. A method for ascertaining control data for a gripping device (120, 122) by using an ML model (142, 162) as claimed in claim 4,
the method being designed and configured to grip an item (200, 210, 220, 300, 310) and comprising the following steps:
capturing an image (132) of the item (200, 210, 220, 300, 310),
determining at least one item parameter (202, 212, 222, 302, 312) for the captured item (200, 210, 220, 300, 310),
ascertaining control data for a gripping device (120, 122) for gripping the item (200, 210, 220, 300, 310) at least one grip point (205, 215, 225, 305, 315),
characterized
in that the at least one grip point (205, 215, 225, 305, 315) on the item (200, 210, 220, 300, 310) is ascertained using the ML model (142, 162),
in particular in that the at least one item parameter (202, 212, 222, 302, 312) is determined and/or the control data for the gripping device (120, 122) are ascertained using the ML model (142, 162).

6. A system (100) for gripping an item,
comprising an optical capture device (130) for capturing an image (132) of the item (200, 210, 220, 300, 310),
a data processing device (140, 150, 190) for determining at least one item parameter (202, 212, 222, 302, 312) of the item (200, 210, 220, 300, 310) and/or for ascertaining control data for a gripping device (120, 122) for gripping the item (200, 210, 220, 300, 310),
characterized
in that the system (100) comprises an ML model (142, 162) as claimed in claim 4, and
in that the system (100) is designed and configured to perform a method as claimed in claim 5 by using the ML model (142, 162).

7. The system as claimed in claim 6,
characterized
in that the data processing device (140, 150, 190) is in the form of and configured as a modular programmable logic controller (150) having a central module (152) and a further module (160), or comprises a programmable logic controller (150) such as this, and
in that the further module (160) comprises the ML model (142, 162).

8. The system as claimed in claim 6,
characterized
in that the data processing device (140, 150, 190) comprises an edge device (190) or is in the form of and configured as an edge device (190),
and in that the edge device (190) furthermore comprises the ML model (142, 162).
